(19) United States
(12) Patent Application Publication
(10) Pub. No.: US 2025/0180980 A1
(43) Pub. Date: Jun. 5, 2025

(54) METHOD, SYSTEM AND ELECTRONIC APPARATUS FOR MASK FEATURE OPTIMIZATION

(71) Applicant: Wuhan Yuwei Optical Software Co., Ltd., Hubei (CN)

(72) Inventor: Haiqing Wei, Hubei (CN)

(73) Assignee: Wuhan Yuwei Optical Software Co., Ltd., Hubei (CN)

(21) Appl. No.: 18/412,977

(22) Filed: Jan. 15, 2024

(30) Foreign Application Priority Data
Dec. 5, 2023 (CN) 202311653960.3

(51) Int. Cl. G03F 1/36; G03F 1/70; G03F 7/20

(52) U.S. Cl. CPC G03F 1/36; G03F 1/70; G03F 7/20

(57) ABSTRACT

The disclosure provides a method and system for mask feature optimization and belongs to the field of computational lithography. The method includes: acquiring a new contour after the edges of the main pattern of a mask are moved inward or outward by a predetermined distance; setting a region inside the new contour as the shadow region when the movement is an inward movement and setting a region outside the new contour as the shadow region when the movement is an outward movement; screening an acquired mask gradient field solved by inverse lithography based on the shadow region to keep only the mask gradient field inside the region; and generating a sub resolution assist/inverse feature of the mask based on the screened mask gradient field.

### CROSS-REFERENCE TO RELATED APPLICATION

This application claims the priority benefit of China application serial no. 202311653960.3, filed on Dec. 5, 2023. The entirety of the above-mentioned patent application is hereby incorporated by reference herein and made a part of this specification.

### BACKGROUND

### Technical Field

The disclosure belongs to the field of computational lithography, and in particular, relates to a method, system and an electronic apparatus for mask feature optimization.

### Description of Related Art

In the layout design of integrated circuits, there are both dense features and sparse features. In particular, the design of logic devices has more diverse shapes. The process windows for dense features and sparse features are inconsistent most of the time during lithography exposure. With the further reduction of critical dimension, it is necessary to introduce a forward sub-resolution assist feature (SRAF) or a sub-resolution inverse feature (SRIF) in the mask optimization design. In this way, process differences caused by different feature densities in integrated circuit layout may be reduced, and the mask optimization effect may be further improved. In the meantime, the uniformity of the depth of focus and process windows may be enhanced. The size of the added assist feature shall be smaller than the imaging resolution of the lithography system, so that it will not form an exposure feature by itself during exposure. Meanwhile, due to the coherence of light, it will have a certain impact on the imaging intensity distribution of the surrounding mask features. Adding SRAF is a technology introduced at 90 nm node and has become a key auxiliary means for mask optimization in integrated circuit manufacturing at 40 nm and smaller nodes.

Currently, the commonly used SRAF generation methods include rule-based SRAF and model-based SRAF. Rule-based generation methods are mainly based on rule tables that generated from accumulated experimental experience of mask optimization, in which the SRAFs of specific shape, size, and arrangement are placed in specific regions around specific mask features. This method requires a large amount of experimental experience to establish the rule table. If the process changes, the rule table needs to be re-accumulated and re-formulated based on the experimental results. The currently-available model-based SRAF generation method is actually an adjustment method for the SRAF. Experience is also needed to determine the number and initial placement position of the SRAFs, and the size and adjustment position of the SRAFs are set as variable parameters. According to the simulated exposure imaging results, the SRAF related parameters are adjusted, and it is determined whether the SRAFs meet the requirement of a certain distance from the main pattern through mask rule check (MRC) to avoid new manufacturing challenges.

In view of the above, the currently-available SRAF generation method needs to be based on experience and requires continuous adjustments and a large amount of MRC determinations, and the steps are relatively complicated and cumbersome. Moreover, for new processes, an effective assist feature cannot be quickly generated, and the efficiency is low.

### SUMMARY

In view of the defects of the related art, the disclosure aims to provide a method, system and an electronic apparatus for mask feature optimization to solve the problems of complicated process steps for generating and adjusting SRAFs and SRIFs, the need for a large number of experiments to accumulate experience, and low efficiency.

To achieve the above, the disclosure provides a method for optimizing a mask feature, and the method includes the following steps.

A new contour is acquired after the edges of the main pattern of a mask are moved inward or outward by a predetermined distance.

A region inside the new contour is set as the shadow region of the main pattern when the movement is an inward movement, and a region outside the new contour feature is set as the shadow region of the main pattern when the movement is an outward movement.

An acquired mask gradient field solved by inverse lithography is screened based on the shadow region of the main pattern to keep only the mask gradient field inside the region.

SRAFs or SRIFs of the mask are generated based on the screened mask gradient field.

It should be noted that the mask gradient field mentioned in the disclosure refers to the gradient field calculated in each iteration of the model-based inverse lithography method, and is a reference gradient field used to indicate how the mask needs to change. To be specific, the calculation method of the mask gradient field can be any currently-available method of inverse lithography (e.g., optical proximity correction (OPC) or inverse lithography technology (ILT)), which is not particularly limited in the disclosure.

To be specific, in the currently-available SRAF or SRIF generation process, a distance between the generated sub resolution assist/inverse feature and the main pattern needs to be judged during the MRC. If the distance is excessively close, the design fails to avoid the impact on the original main pattern during the manufacturing process. In the disclosure, by screening the mask gradient field, the generated sub resolution assist/inverse feature naturally has a predetermined distance from the main pattern. For any main pattern, SRAF/SRIFs that meet manufacturing requirements and have positive impacts on exposure can be effectively generated, so that the work of MRC is significantly reduced, and the efficiency of SRAF/SRIF generation is improved.

In an embodiment, if the region outside the new contour is set as the shadow region of the main pattern, the generated sub resolution assist/inverse feature is a sub resolution assist feature (SRAF).

If the region inside the new contour is set as the shadow region of the main pattern, the generated sub resolution assist/inverse feature is a sub resolution inverse feature (SRIF).

In an embodiment, the acquiring the new contour after the edges of the main pattern of the mask are moved inward or outward by the predetermined distance includes the following. A partial derivative function is placed at each point on the edges of the main pattern of the mask to acquire a vector gradient field.

The vector gradient field is integrated, and the integrated value is treated as a gray scale value to acquire a gray scale auxiliary image.

The edges of the main pattern are segmented, and a representative position of each edge segment is determined. The gray scale value at each edge segment on the auxiliary image is modulated based on the predetermined distance and the acquired vector gradient field, and then the gray scale value in its vicinity is modulated through a smoothing function, so that the gray scale value in a modulation region changes continuously to acquire an updated auxiliary image.

The updated auxiliary image is intercepted by adopting a truncation threshold, and a new polygon contour is extracted. The polygon contour is treated as the new contour, if the difference value between edge position distance of each point on the edges, which is calculated between the currently extracted polygon contour and the original main pattern, and the predetermined distance, is less than the preset small value. Otherwise, the gray scale value of each point where the difference value is not less than the preset small value and the ones in its vicinity are iteratively modulated on the updated auxiliary image until the difference value of each point on the finally extracted polygon contour is less than the preset small value.

In an embodiment, iteratively modulating the gray scale value of each point where the difference value is not less than the preset small value and the ones in its vicinity on the updated auxiliary image specifically includes the following.

A partial derivative function is placed at each point in the currently extracted polygon contour where the difference value is not less than the preset small value to acquire a new vector gradient field.

Based on the newly acquired vector gradient field, the edge position distance corresponding to each point, and the predetermined distance, the gray scale value of each point is modulated on the updated auxiliary image, and the gray scale value in its vicinity is modulated by adopting a smoothing function, so that the gray scale value in the modulation region changes continuously to acquire the further updated auxiliary image.

In an embodiment, modulating the gray scale value of each point on the updated auxiliary image specifically includes the following. Based on the current gray scale value, a product of the scalar gradient corresponding to the vector gradient field of each point of the current polygon contour, and the difference value between the current edge position distance and the predetermined distance, is accumulated to acquire the modulated gray scale value.

In an embodiment, screening the acquired mask gradient field solved by inverse lithography based on the shadow region of the main pattern includes the following.

The shadow region of the main pattern is rasterized into a gray scale pixel image based on the boundary contour curves of the shadow region, on which the pixel value deep into the shadow region is set to 1, the pixel value far away from the shadow region set to 0, and the pixel value near the edge of the shadow region is set smoothly transition from 1 to 0.

A point-by-point operation is performed on the pixel value of each point on the gray scale pixel image and the pixel value of each point in the mask gradient field to implement screening of the mask gradient field.

In an embodiment, screening the acquired mask gradient field solved by inverse lithography based on the shadow region of the main pattern includes the following.

A Boolean function whose coordinate points are located inside its contour is constructed based on the boundary contour curves of the shadow region.

The mask gradient field is screened based on the Boolean function.

In an embodiment, generating the sub resolution assist/inverse feature based on the screened mask gradient field includes the following.

A corresponding sub resolution assist or inverse feature is placed according to the position of a ridge or a valley of the screened mask gradient field.

In an embodiment, generating the sub resolution assist/inverse feature based on the screened mask gradient field includes the following.

A positive threshold and a negative threshold of the gradient field are set.

If the region outside the new contour is set as the shadow region and then when the value of the mask gradient field is greater than the positive threshold, the setting value of the mask gradient field at the corresponding position is set to 1, and the setting values of the mask gradient field at the rest of the positions are set to 0. If the region inside the new contour is set as the shadow region and then when the value of the mask gradient field is less than the negative threshold, the setting value of the mask gradient field at the corresponding position is set to 1, and the setting values of the mask gradient field at the rest of the positions are set to 0.

A pixelated feature corresponding to the mask gradient field at the position where the setting value is 1 is treated as the generated sub resolution assist/inverse feature.

In an embodiment, the main pattern is an arbitrary curvilinear pattern or a Manhattan pattern.

In an embodiment, the predetermined distance refers to the mask rule check (MRC) parameter setting.

In the second aspect, the disclosure provides a method for mask optimization, and the method includes the following steps.

Two new contours acquired by moving the edges of main pattern of a mask inward and outward by a predetermined distance are acquired.

A region between the two new contours is treated as a selection region.

An acquired mask gradient field solved by inverse lithography is screened based on the selection region to keep only the mask gradient field inside the region.

The screened mask gradient field is treated as an optional mask gradient field in a main pattern optimization process to prevent the edge of the main pattern from moving an excessively large step during the mask optimization process.

It should be noted that during the mask optimization of the main pattern, the moving step needs to be limited. If the moving step is excessively large, it may cause irreparable distortion of the main pattern. Therefore, the method of the disclosure limits the optional mask gradient field in the main pattern optimization process, to ensure the optimized main pattern will not be distorted.

In this way, low optimization efficiency in the subsequent random optimization process is avoided, and the optimization efficiency and quality of the main pattern are improved within the limited optimization time.

In an embodiment, the predetermined distance refers to the lithography optimization parameter setting.

In the third aspect, the disclosure provides a system for mask feature optimization, including a new contour acquisition module, a shadow region acquisition module, a mask gradient field screening module, and an assist/inverse feature generating module.

The new contour acquisition module is configured to acquire a new contour after the edges of the main pattern of a mask are moved inward or outward by a predetermined distance.

The shadow region acquisition module is configured to set a region inside the new contour as the shadow region when the movement is an inward movement and set the region outside the new contour as the shadow region when the movement is an outward movement.

The mask gradient field screening module is configured to screen an acquired mask gradient field solved by inverse lithography based on the shadow region to keep only the mask gradient field inside the region.

The assist/inverse feature generating module is configured to generate a sub resolution assist/inverse feature of the mask based on the screened mask gradient field.

In the fourth aspect, the disclosure provides a system for mask feature optimization, including a new contour acquisition module, a selection region determining module, a mask gradient field screening module, and a mask gradient field setting module.

The new contour acquisition module is configured to acquire two new contours acquired by moving the edges of the main pattern of a mask inward and outward by a predetermined distance.

The selection region determining module is configured to treat the region between the two new contours as the selection region.

The mask gradient field screening module is configured to screen an acquired mask gradient field solved by inverse lithography based on the selection region to keep only the mask gradient field inside the region.

The mask gradient field setting module is configured to treat the screened mask gradient field as an optional mask gradient field in a main pattern optimization process to prevent the edges of the main pattern from moving an excessively large step during the mask optimization process.

In the fifth aspect, the disclosure provides an electronic apparatus including at least one memory for storing a program and at least one processor configured to execute the program stored in the at least one memory. When the program stored in the memory is executed, the processor is used to execute the method described in at least one of the first aspect, any possible implementation manner of the first aspect, the second aspect, or any possible implementation manner of the second aspect.

In the sixth aspect, the disclosure provides a computer-readable storage medium, and the computer-readable storage medium stores a computer program. When the computer program is running on the processor, the processor is enabled to execute the method described in at least one of the first aspect, any possible implementation manner of the first aspect, the second aspect, or any possible implementation manner of the second aspect.

In the seventh aspect, the disclosure provides a computer program product. When the computer program product is running on the processor, the processor is enabled to execute the method described in at least one of the first aspect, any possible implementation manner of the first aspect, the second aspect, or any possible implementation manner of the second aspect.

It can be understood that the beneficial effects of the above third to seventh aspects can be referred to the relevant description in the above first and second aspects, so description thereof is not repeated herein.

To sum up, the above technical solutions provided by the disclosure have the following beneficial effects compared with the related art.

The disclosure provides a method, a system and an electronic apparatus for mask feature optimization. The main pattern is used as the basic pattern, and the level set-based curvilinear polygon scaling method is used to iteratively obtain the shadow region around the main pattern by a certain distance. The shadow region of the main pattern is used to screen the gradient vector field of the mask. According to the screened gradient vector field, the SRAF or SRIF generation method is selected to generate and optimize the SRAF or SRIF. The SRAF or SRIF generation involved in this method is model-based, not rule-based, and does not rely on experimental experience. Therefore, for mask pattern without accumulated experience, effective SRAF or SRIF can still be generated. Furthermore, for some patterns that have accumulated experience, the original layout rules can be broken and new assist or inverse feature layout can be obtained. During SRAF or SRIF generation, the mask gradient field is screened using the shadow region of the main pattern. Therefore, the generated SRAF or SRIF meets the condition of being at a certain distance from the edge of the main pattern, and there is no need to additionally consider how to determine and verify the distance between the SRAF or SRIF and the main pattern. The generation efficiency and quality of SRAF or SRIF are improved.

The disclosure provides a method, a system and an electronic apparatus for mask feature optimization. The provided SRAF or SRIF generation and extraction method can be applied to the case where the main pattern is Manhattan pattern and can also be applied to the case where the main pattern is arbitrary curvilinear pattern with complex edge contours after OPC or ILT. The SRAF or SRIF described in the disclosure is not limited by its shape and can be a Manhattan feature or any curvilinear feature. Benefiting from the level set-based method of scaling a curvilinear polygon to generate the shadow region, the disclosure is applicable to any curvilinear polygons. Further, the generation of the SRAF or SRIF is based on the gradient field and is not limited by the generation rules.

The disclosure provides a method, a system and an electronic apparatus for mask feature optimization. The idea of the method is not limited to SRAF or SRIF generation. There are many other application scenarios and methods, which can be applied but not limited to the following scenarios. In the model-based OPC or ILT, for the main pattern optimization, when how the edge of the main pattern moves is more concerned and the gradient values at the rest of the locations are not of interest, different regions can be set and screened out as needed. By applying the idea of the method described in the disclosure, the region surrounded by two contour curves extending a certain distance outward and shrinking a certain distance inward of the main pattern can be set as the shadow region. This region is an annular zone that includes the edge contour of the main pattern. The inside of this region is set as the selection region, and the outside is the non-selection region, that is, the blocking region, and the mask gradient field is screened. Therefore, it can be ensured that only the gradient field within the annular region of the shadow region has values after screening, and the edge movement of the main pattern is limited to the annular region to facilitate subsequent processing. The moving step in the optimization process of the main pattern is limited, unnecessary steps introduced in the optimization process are avoided, the optimization efficiency and quality of the main pattern are improved, and a large amount of inspection and screening work after optimization is avoided.

It should be noted that the main pattern and the sub resolution assist/inverse feature are both mask features. It can be seen that the method provided by the disclosure is suitable for the generation and optimization process of mask features, so the disclosure can be called a mask feature optimization method or a mask feature generation method. They are essentially the same. The technical solution provided by the disclosure can be used to improve the optimization/generation efficiency and quality of the mask feature and improve the entire optimization/generation process of the mask.

### BRIEF DESCRIPTION OF THE DRAWINGS

FIG. 1 is a flow chart of a method for mask feature optimization provided by an embodiment of the disclosure.

FIG. 2 is a flow chart for implementing a sub resolution assist feature (SRAF) extraction method using a shadow region constraint of a main pattern provided by an embodiment of the disclosure.

FIG. 3 is a specific implementation process for generating the shadow region of the main pattern provided by an embodiment of the disclosure.

FIG. 4 is a specific implementation process for screening a mask gradient field using the shadow region according to an embodiment of the disclosure.

FIG. 5 is a specific implementation process of using the shadow region to generate a SRAF constraint according to an embodiment of the disclosure.

FIG. 6 is a specific implementation process of using the shadow region to generate a sub resolution inverse feature (SRIF) constraint according to an embodiment of the disclosure.

FIG. 7 is another flow chart of a method for optimizing a mask feature provided by an embodiment of the disclosure.

FIG. 8 is a specific implementation process of gradient field screening using a shadow region for optimal design of a main pattern provided by an embodiment of the disclosure.

FIG. 9 is a specific implementation process of Embodiment 1 provided by an embodiment of the disclosure.

FIG. 10 is an architectural diagram of a system for mask feature optimization provided by an embodiment of the disclosure.

FIG. 11 is an architectural diagram of another system for mask feature optimization provided by an embodiment of the disclosure.

### DESCRIPTION OF THE EMBODIMENTS

In order to make the objectives, technical solutions, and advantages of the disclosure clearer and more comprehensible, the disclosure is further described in detail with reference to the drawings and embodiments. It should be understood that the specific embodiments described herein serve to explain the disclosure merely and are not used to limit the disclosure.

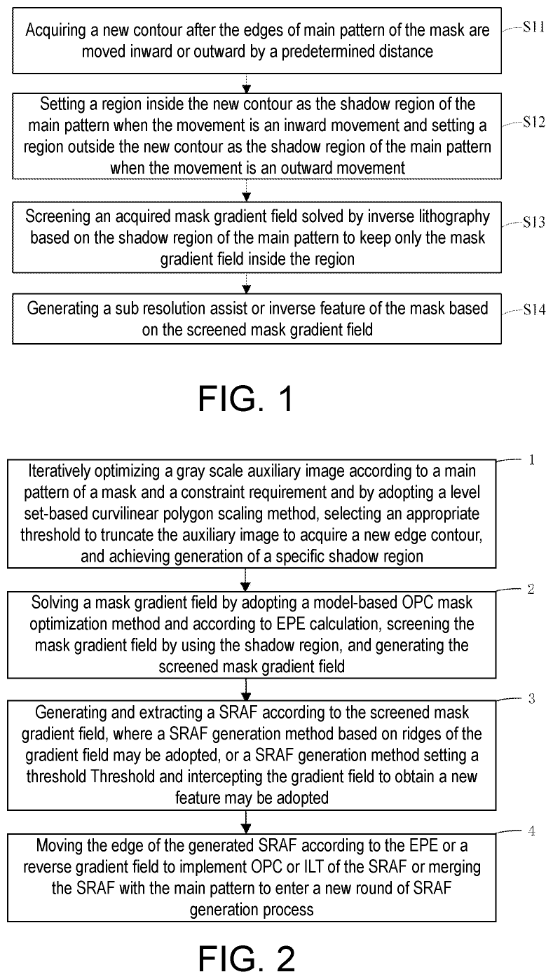

FIG. 1 is a flow chart of a method for mask feature optimization provided by an embodiment of the disclosure. As shown in FIG. 1, the following steps are included.

In S11, a new contour is acquired after the edges of main pattern of the mask are moved inward or outward by a predetermined distance.

In S12, when the movement is an inward movement, a region inside the new contour is set as the shadow region of the main pattern, and when the movement is an outward movement, a region outside the new contour is set as the shadow region of the main pattern.

In S13, based on the shadow region of the main pattern, an acquired mask gradient field solved by inverse lithography is screened to keep only the mask gradient field inside the region.

In S14, sub resolution assist or inverse feature of the mask is generated based on the screened mask gradient field.

To be specific, the specific implementation solution of using a shadow region to screen the mask gradient field involved in the disclosure include but not limited to the following solutions. 1) Based on the boundary contour curve of the shadow region, the vectorized shadow region is rasterized into a gray scale pixel image. Its pixel value gradually approaches 1 (or 0) when it goes deep into the shadow region, gradually approaches 0 (or 1) when it is outside and away from the shadow region, and achieves a smooth transition from 0 to 1 near the boundary contour curve of the shadow region. The gray scale pixel image is used to perform a point-by-point multiplication operation with each pixel of the mask gradient field to achieve data screening.

2) By treating the boundary contour curve of the shadow region as polygon data, a Boolean function that implements “coordinate points located inside the polygon” (point in polygon) is constructed to indicate whether a given coordinate point is located inside the shadow region to achieve data screening.

To be specific, generation of a sub resolution assist feature (SRAF) or a sub resolution inverse feature (SRIF) described in the disclosure may include but not limited to the following two methods. First, through generation of ridges in the screened gradient field, that is, in the screened gradient field, if there are obvious ridges or valleys, the SRAF or SRIF is placed at the location. The width of the generated SRAF or SRIF is a function that depends on an absolute value of the gradient where the gradient field ridges are located. Second, through setting of a threshold, the screened gradient field is intercepted by the threshold and 0-1 binarized, and the formed new feature is the SRAF or SRIF.

To be specific, the method provided by the disclosure may be used to generate SRAF outside the main pattern and may also be used to generate SRIF inside the main pattern. By selecting different shadow regions, judging the sign of the gradient field, choosing an assist feature to be placed at the valleys of the gradient field, or setting the required threshold for interception and 0-1 binarization, the SRIF inside the main pattern may also be generated.

In an embodiment, the disclosure provides a method for extracting a sub resolution assist feature using a shadow region of the main pattern constraint, and the method includes the steps shown in FIG. 2.

In Step 1, a shadow region is generated based on the main pattern of a mask and constraint requirements. The main pattern is the pattern before SRAF or SRIF generated on the mask. The constraint requirements may be different for different patterns and targets. In an optional embodiment, the generated SRAF that needs to be a certain distance dis away from the main pattern is treated as an example. A level set-based curvilinear polygon scaling method is adopted. To be specific, based on the contour edges of the main pattern, a gray scale auxiliary image is generated and iteratively optimized, and an appropriate threshold is selected to truncate the auxiliary image to acquire an edge contour that meets the requirement. In the aforementioned optional embodiment, each point on the edges of the acquired new contour shall be at a set distance dis away from the original contour of the main pattern. Based on the new contour and combined with the constraint requirements, a specific shadow region is generated. In an optional embodiment, the constraint requirement is to generate the SRAF outside the main pattern, and the generated shadow region could be set such that the inside of the newly generated contour is a blocking region and the outside is a selection region. It should be noted that in the level set-based polygon scaling, the gray scale auxiliary image is an optimized auxiliary image in the acquisition process of the shadow region and is not related to the SRAF.

In Step 2, a mask gradient field is screened using the shadow region generated in Step 1 to obtain the screened gradient field. The mask gradient field is acquired by using a model-based optical proximity correction (OPC) mask optimization method, which is an inverse solution based on the simulated calculation of edge placement error (EPE).

In Step 3, the SRAF is generated and extracted based on the screened mask gradient field generated in Step 2. Generation and extraction of the SRAF may include but not limited to the following two methods. First, through generation of the ridges in the gradient field, that is, in the screened gradient field, if there are obvious ridges or valleys, the SRAF is placed at the location. The width of the generated SRAF is a function that depends on the absolute value of the gradient where the gradient field ridges are located. For example, the width of the SRAF is proportional to the absolute value of the gradient. Second, through setting of a threshold, the screened gradient field is intercepted by the threshold and 0-1 binarized, and the formed new feature is the SRAF.

In Step 4, the boundary contour curve of the generated SRAF or SRIF may be similar to the boundary contour curve of the main pattern, and the boundary may be moved according to EPE or an inverse gradient field. Therefore, OPC or inverse lithography technology (ILT) may be performed on the generated SRAF or SRIF. Further, the generated SRAF or SRIF may be merged with the original main pattern, and the shadow region generation method of the disclosure is used to generate shadow region to limit a legal region for the next step of SRAF or SRIF generation. In this way, it is ensured that the distances between the SRAF or SRIF generated in the next step and the original main pattern, also and the already generated SRAF or SRIF, are not less than a predetermined distance.

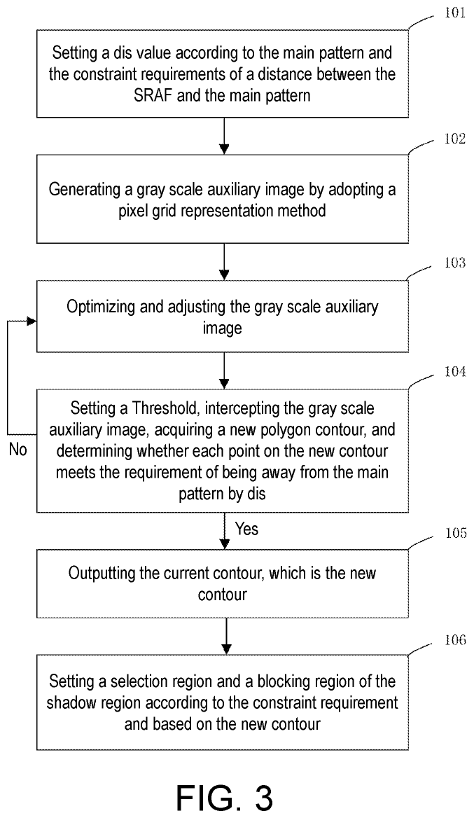

In an embodiment, the specific optimization solution process of the level set-based polygon scaling and curve contour movement method described in Step 1 and the shadow region setting method are shown in FIG. 3, and the main steps include the following.

In Step 101, the dis value is set according to the main pattern of the mask and the constraint requirements. The main pattern may be a Manhattan pattern or an arbitrary curvilinear pattern with complex edge contours after OPC or ILT. The constraint requirements are represented by the most common distance constraint between the SRAF/SRIF and the contour of the main pattern. The SRAF/SRIF need to be at a certain distance from the edge contour of the main pattern to avoid introducing new manufacturability issues, which is not limited to the SRAF added in the surrounding region outside the main pattern or the SRIF inside the main pattern.

In Step 102, based on the main pattern in Step 101, a gray scale auxiliary image is generated by adopting a pixel grid representation method.

In Step 103, the gray scale auxiliary image is optimized and adjusted according to a vector gradient field. The vector gradient field is generated from a difference value as the observation quantity between the contour distance and the dis value. The contour distance is calculated on each point on the contour edges between the current contour and the one of original main pattern.

In Step 104, an appropriate Threshold is set, the gray scale auxiliary image in Step 103 is intercepted and processed into 0-1 binarization to obtain a new polygon contour. The distance between the newly generated contour and the one of the original main pattern is calculated on each point on the edges to determine whether the distance dis requirement is met. If the requirement is met, iteration is ended and Step 105 is performed next. If the requirement is not met, a new vector gradient field is calculated, Step 103 is performed again, and the iterative optimization continues.

In Step 105, the current contour is outputted, which is the new contour that meets the requirement.

In Step 106, according to the new contour generated in Step 105, a screening region is set according to the constraint requirement, and the generation of the shadow region of the main pattern is completed.

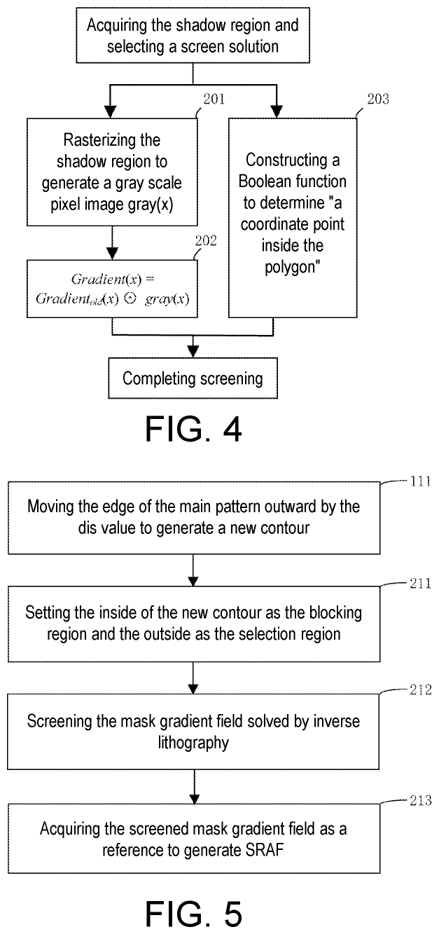

Further, the specific implementation process of screening the mask gradient field by using the shadow region in the disclosure may be selected from but not limited to the two solutions as shown in FIG. 4.

The first solution is as shown in 201 and 202. In Step 201, based on the boundary contour curve of the shadow region, the vectorized shadow region is rasterized into a gray scale pixel image gray (x). Its pixel value gradually approaches 1 (or 0) when it goes deep into the shadow region, gradually approaches 0 (or 1) when it is outside and away from the shadow region, and achieves a smooth transition from 0 to 1 near the boundary contour curve of the shadow region. It can be implemented by but not limited to using the Sigmoid function. In Step 202, the gray scale pixel image is used to perform a point-by-point multiplication operation with each pixel of the mask gradient field, Gradient (x)=Gradientola (x) @ gray (x), to achieve data screening.

The second solution is as shown in 203, by treating the boundary contour curve of the shadow region as polygon data, a Boolean function that implements “a coordinate point inside the polygon” (point in polygon) is constructed to indicate whether a given coordinate point is located inside the shadow region to achieve data screening.

Further, in the specific implementation process of using the shadow region to block and screen the mask gradient field described in the disclosure, different screening regions may be set according to different constraints.

In an optional embodiment, when the intention is to generate the SRAF outside the main pattern, the specific implementation process is shown in FIG. 5.

In Step 111, a level set-based polygon enlargement and contour curve movement method is used to move the edge contour of the main pattern outward by the dis value to generate a new contour. The dis value is the required minimum distance between SRAF and the main pattern.

In Step 211, the outside of the new contour generated in Step 111 is set as the selection region, and the inside is the non-selection region, that is, the blocking region. That is, the main pattern is in the blocking region, the region extending dis from the edge of the main pattern is also blocked, and the gradient field of the corresponding region is to be screened out.

In Step 212, the shadow region in Step 211 is used to screen the mask gradient field solved by inverse lithography. In this way, it is ensured that when the SRAF is subsequently generated from the gradient field, the SRAF only exists in the regions that are away from the main pattern by the dis distance.

In Step 213, the gradient field screened in Step 212 is used as a reference gradient field to generate SRAF.

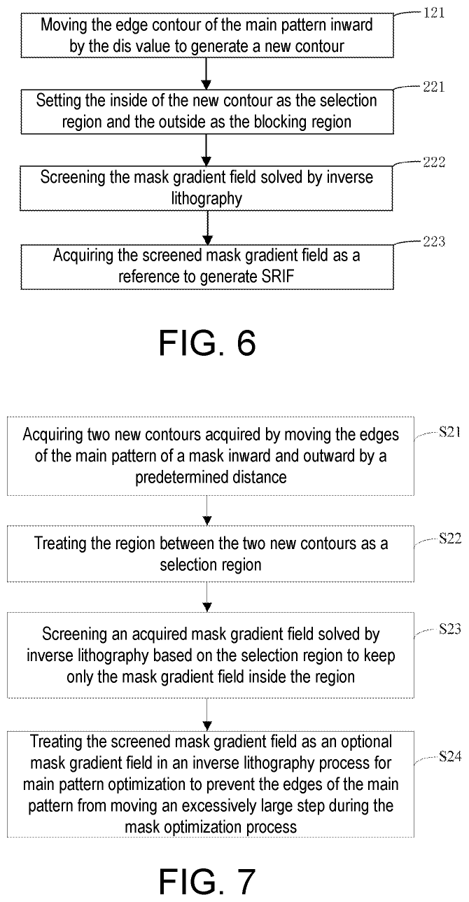

In an optional embodiment, when the intention is to generate the SRIF inside the main pattern, the specific implementation process is shown in FIG. 6.

In Step 121, a level set-based polygon reduction and contour curve movement method is used to move the edge contour of the main pattern inward by the dis value to generate a new contour. The dis value is the required minimum distance between the SRIF and the boundary of the main pattern.

In Step 221, the inside of the new contour generated in Step 121 is set as the selection region, and the outside is set as the blocking region. That is, only the smaller region inside the main pattern, that is dis distance away from the boundary contour of the main pattern, is the selection region, that is, the shadow region.

In Step 222, the shadow region generated in Step 221 is used to screen the mask gradient field. The shadow region generated in Step 221 ensures that the SRIF can only exist within the main pattern and is at least dis distance from the boundary contour of the main pattern.

In Step 223, the screened gradient field in Step 222 is used as the reference gradient field to generate SRIF.

It should be noted that the method for generating the sub resolution assist or inverse feature described in the disclosure may adopt different methods. In an optional embodiment, when intending to generate an SRAF (or SRIF), if there are ridges (or valleys) in the selection region through the screened gradient field, a scattering bar may be placed where the ridges (or valleys) are provided to generate the SRAF (or SRIF). The way to determine whether there are ridges (or valleys) can be but is not limited to, deriving the gradient field in the horizontal and vertical directions, that is, obtaining the second-order partial derivative distribution. If there is a region in the distribution where the continuous value is not 0, or the absolute value is greater than the preset small value, there are gradient field ridges (or valleys) inside the region, and the SRAF (or SRIF) may be placed according to the distribution. The width of the generated SRAF (or SRIF) is a function that depends on the absolute value of the gradient where the gradient field ridges (or valleys) are located. For example, the width of the SRAF is proportional to the absolute value of the gradient.

A person having ordinary skill in the art can choose to generally place the SRAF at the ridges of the gradient field and generally place the SRIF at the valleys of the gradient field. A person having ordinary skill in the art can also select a suitable position of the gradient field to place the corresponding sub resolution assist or inverse feature according to actual needs, which is not particularly limited in the disclosure.

To be specific, the generation of the sub resolution assist/inverse feature based on the screened mask gradient field includes the following. A positive threshold and a negative threshold of the gradient field are set. If the region outside the new contour is set as the shadow region of the main pattern and then when a value of the mask gradient field is greater than the positive threshold, the setting value of the mask gradient field at corresponding position is set to 1, and the setting values at other positions are set to 0. If the region inside the new contour is set as the shadow region of the main pattern and then when the value of the mask gradient field is less than the negative threshold, the setting value of the mask gradient field at the corresponding position is set to 1 and the setting values at other positions are set to 0. A pixelated feature corresponding to the mask gradient field at the position where the setting value is 1 is treated as the generated sub resolution assist/inverse feature.

In an optional embodiment, Threshold is set, and the screened gradient field is intercepted by the Threshold and 0-1 binarized, for example but not limited to the following. For the region where the absolute value of the gradient field exceeds Threshold, that is, |Grad|≥Threshold, its value is set to 1 (or 0), and the value of the region less than Threshold is set to 0 (or 1), and a sub resolution assist/inverse feature is thereby placed. Depending on the sign of the gradient field, SRAF or SRIF is specifically placed.

FIG. 7 is a flow chart of another method for mask feature optimization provided by an embodiment of the disclosure. As shown in FIG. 7, the following steps are included.

In S21, two new contours are acquired by moving the edges of the main pattern of a mask inward and outward by a predetermined distance.

In S22, the region between the two new contours is treated as a selection region.

In S23, an acquired mask gradient field solved by inverse lithography based on the selection region is screened to keep only the mask gradient field inside the region.

In S24, the screened mask gradient field is treated as an optional mask gradient field in an inverse lithography process for main pattern optimization to prevent the edges of the main pattern from moving an excessively large step during the mask optimization process.

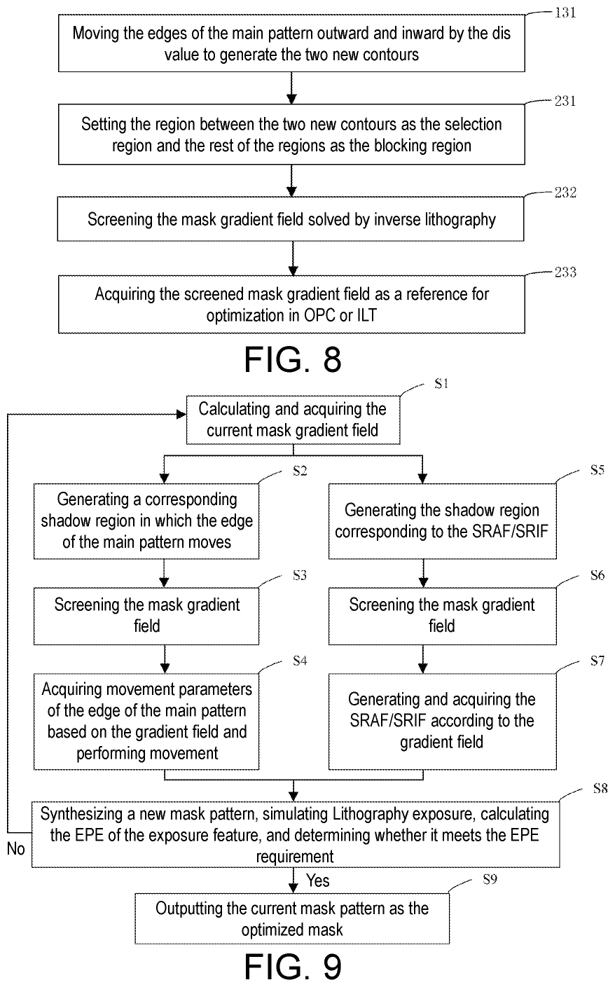

Further, in an optional embodiment, when it is intended to move the edge of the main pattern, the specific implementation process is as shown in FIG. 8.

In Step 131, the level set-based polygon scaling and contour curve moving method is used to move the edges of the main pattern outward and inward by the dis value to generate the two new contours. The dis value herein is the predetermined distance to limit the movement of the mask edge, which may be presented in nanometers or the number of pixels.

In Step 231, according to the two new contours generated in Step 131, an annular region between the two contours is set as the selection region, and the rest of the regions are set as the blocking region. In this way, only the region at the distance dis near the edge contour of the main pattern is the selection region, that is, the shadow region.

In Step 232, the shadow region generated in Step 231 is used to screen the mask gradient field. The shadow region generated in Step 231 ensures that only the gradient field near the contour of the main pattern is kept, which helps to screen the gradient value of the edge region that is more concerned during the optimization process of the main pattern on the mask.

In Step 233, the gradient field screened in Step 232 is used as a reference for the main pattern optimization in the OPC or ILT process.

### Embodiment 1

The disclosure is suitable for the generation and extraction of a sub resolution assist/inverse feature in a model-based mask optimization design. The disclosure is described below by taking OPC inverse lithography mask optimization as an example, and the specific implementation is shown in FIG. 9. The following steps are included.

In step S1, the current mask gradient field is calculated and acquired. The gradient field calculation herein may use but not limited to the adjoint gradient solved by inverse lithography, and may use but not limited to the following two methods for calculation. First, after the forward simulation of the lithography exposure process, edge contour points or contour curves are extracted from the simulated resist image, and EPE is calculated by comparing the simulated contour points or contour curves with the preset targets. In this method, the adjoint gradient is obtained through the inverse transfer of the EPE through each stage of the lithography model. Second, after the forward lithography simulation, the simulated signal value is extracted at the position of the predetermined target points, and the signal error is calculated by comparing the simulated signal value with the predetermined threshold. The signal error is propagated back through the inverse stages of the lithography model to obtain the adjoint gradient.

In Step S2, a range distance Bias of an interest region near the main pattern is set, and based on the main pattern of the mask, a corresponding shadow region is generated in which the edge contour of the main pattern moves. That is, the edge contour of the main pattern is moved outward and inward by Bias, the region between the indented contour and the expanded contour is set as the selection region, and other unselected regions are the blocking regions.

In Step S3, the shadow region generated in Step S2 is used and a specific screening solution in FIG. 4 is selected to screen the mask gradient field calculated in Step S1. The screened gradient field only has values near the edge contour of the main pattern.

In Step S4, based on the gradient field screened in Step S3, movement parameters of the edge of the main pattern are acquired, and movements are performed. The movement parameters are mainly a movement direction and a step of each edge segment. The method of acquiring the movement parameters of the edge through the gradient field can adopt but not limited to various numerical adjustment methods of adaptive step acquisition.

In Step S5, the minimum allowable distance dis value between the sub resolution assist/inverse feature and the edge of the main pattern is set, and the shadow region corresponding to the SRAF (or SRIF) is generated. For the process of intending to generate the SRAF, the edge contour of the main pattern is expanded outward by dis, the inner region is set as the blocking region, and the outer is set as the selection region. For the process of intending to generate the SRIF, the edge contour of the main pattern is reduced inward by dis, the inner region is set as the selection region, and the outer is set as the blocking region. For processes intended to produce both SRAF and SRIF, the edge contour of the main pattern is expanded outward and inward by dis, the region between the expanded contour and the indented contour is set as the blocking region, and the rest of the regions are set as the selection region.

In Step S6, the shadow region generated in Step S5 is used and a specific screening solution in FIG. 4 is selected to screen the mask gradient field calculated in Step S1. The screened gradient field only has values in specific regions. To be specific, after the corresponding shadow region that generates the SRAF is screened, the gradient field only has values outside the main pattern and in the region away from the edge of the main pattern by dis. After the corresponding shadow region that generates the SRIF is screened, the gradient field only has values inside the main pattern and in the region away from edge of the main pattern by dis. After the corresponding shadow regions that generate both the SRAF and the SRIF, the gradient field may have values both outside and inside the main pattern and in regions away from the edge contour of the main pattern by dis.

In Step S7, the sub resolution assist/inverse feature is generated and extracted based on the gradient field screened in Step S6. An extraction method based on gradient field ridges/valleys or a generation extraction method based on thresholds may be used, but it is not limited thereto.

In Step S8, the main pattern of the mask generated in Step S4 and the sub resolution assist/inverse feature generated in Step S7 are merged, and a new mask pattern is generated. Lithography exposure is simulated, the EPE after exposure is calculated, and it is determined whether the EPE requirement or other iteration stop conditions are met. If the stop conditions are met, Step S9 is performed instead, and the current mask pattern is outputted as the optimized mask. If the stop conditions are not met, Step S1 is performed, and the current mask gradient field is calculated through inverse solution to enter a new round of iteration.

It is worth mentioning that in the actual mask optimization design process, the above steps may be adjusted, disassembled, or reorganized according to the actual situation. For example, in a process or iteration in which only the edge of the main pattern is moved, only steps S2 to S4 may be performed, and steps S5 to S7 need not be performed. In the process or iteration in which the main pattern is no longer adjusted and only the generation of the sub resolution assist/inverse feature is considered, only steps S5 to S7 may be performed, and there is no need to perform steps S2 to S4. In addition, a mask optimization strategy based on different iteration stages may be designed, for example, but not limited to, in the first few iterations, only the main pattern is adjusted. In the middle iterations, the main pattern is fixed and only the sub resolution assist/inverse feature is generated and adjusted. In the last few iterations, both the main pattern and the sub resolution assist/inverse feature are adjusted together, and so on.

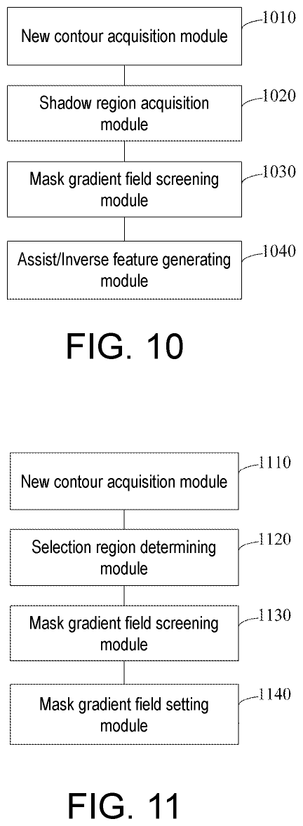

FIG. 10 is an architectural diagram of a system for mask feature optimization provided by an embodiment of the disclosure. As shown in FIG. 10, the system includes a new contour acquisition module 1010, a shadow region acquisition module 1020, a mask gradient field screening module 1030, and an assist/inverse feature generating module 1040.

The new contour acquisition module 1010 is configured to acquire a new contour after the edges of the main pattern of a mask is moved inward or outward by a predetermined distance.

The shadow region acquisition module 1020 is configured to set a region inside the new contour as a shadow region when the movement is an inward movement and set a region outside the new contour as the shadow region when the movement is an outward movement.

The mask gradient field screening module 1030 is configured to screen an acquired mask gradient field solved by inverse lithography based on the shadow region to keep only the mask gradient field inside the shadow region.

The assist/inverse feature generating module 1040 is configured to generate a sub resolution assist/inverse feature of the mask based on the screened mask gradient field.

It can be understood that the detailed functional implementation of the foregoing modules may be found with reference to the introduction in the foregoing method embodiments, and description thereof is not repeated herein.

FIG. 11 is an architectural diagram of another system for mask feature optimization provided by an embodiment of the disclosure.

A new contour acquisition module 1110 is configured to acquire two new contours acquired by moving the edges of the main pattern of a mask inward and outward by a predetermined distance.

A selection region determining module 1120 is configured to treat a region between the two new contours as a selection region.

A mask gradient field screening module 1130 is configured to screen an acquired mask gradient field solved by inverse lithography based on the selection region to keep only the mask gradient field inside the region.

A mask gradient field setting module 1140 is configured to treat the screened mask gradient field as an optional mask gradient field in a main pattern optimization during inverse lithography process to prevent the edges of the main pattern from moving an excessively large step during the mask optimization process.

It can be understood that the detailed functional implementation of the foregoing modules may be found with reference to the introduction in the foregoing method embodiments, and description thereof is not repeated herein.

It should be understood that the abovementioned systems provided in FIG. 10 and FIG. 11 are used to perform the method in the specific embodiments of FIG. 1 to FIG. 9. The implementation principles and technical effects of the corresponding program modules in the systems are similar to those described in the above method. The working process of the systems can be referred to the corresponding process in the above method, so description thereof is not repeated herein.

Based on the method in the foregoing embodiments, an embodiment of the disclosure provides an electronic apparatus. The apparatus may include at least one memory for storing a program and at least one processor for executing the program stored in the memory. Herein, when the program stored in the memory is executed, the processor is used to execute the method described in the above embodiments.

Based on the method in the above embodiments, an embodiment of the disclosure provides a computer-readable storage medium, and the computer-readable storage medium stores a computer program. When the computer program is running on the processor, the processor is enabled to execute the method in the above embodiments.

Based on the method in the above embodiments, an embodiment of the disclosure provides a computer program product. When the computer program product is running on the processor, the processor is enabled to execute the method in the above embodiments.

It can be understood that the processor in the embodiments of the disclosure may be a central processing unit (CPU), may be a general-purpose processor, a digital signal processor (DSP), an application specific integrated circuit (ASIC), or a field programmable gate array (FPGA), or may be a programmable logic device, a transistor logic device, a hardware component, or any combination thereof. The general-purpose processor may be a microprocessor or may also be any conventional processor.

The method steps in the embodiments of the disclosure may be implemented by hardware or by a processor executing software instructions. The software instructions may be formed by a corresponding software module, and the software module may be stored in a random access memory (RAM), a flash memory, a read-only memory (ROM), a programmable ROM (PROM), an erasable PROM (EPROM), an electrically EPROM (EEPROM), a register, a hard disk, a mobile hard disk, a CD-ROM, or any other form of storage media well known in the art. An exemplary storage medium is coupled to the processor, such that the processor can read information from the storage medium and write information to the storage medium. Certainly, the storage medium may also be an integral part of the processor. The processor and storage medium may be located in the ASIC.

All or part of the foregoing embodiments may be implemented by software, hardware, firmware, or any combination thereof. When implementation is performed by using software, it may be implemented in whole or in part in the form of a computer program product. The computer program product includes one or a plurality of computer instructions. When the computer program instructions are loaded and executed on the computer, the processes or functions according to the embodiments of the disclosure will be generated in whole or in part. The computer may be a general purpose computer, a special purpose computer, a computer network, or other programmable apparatuses. The computer instructions may be stored in or transmitted through a computer-readable storage medium. For instance, the computer instruction may be transmitted from one website, computer, server, or data center to another website, computer, server, or data center by wired (e.g., coaxial cable, optical fiber, digital subscriber line (DSL)) or wireless (e.g., infrared, wireless, microwave, etc.) means. The computer-readable storage medium may be any available medium that may be accessed by a computer or a data storage device such as a server or a data center integrated with one or more available media. The available medium may be a magnetic medium (e.g., a floppy disk, a hard disk, or a magnetic tape), an optical medium (e.g., DVD), or a semiconductor medium (e.g., a solid state disk (SSD)), etc.

It can be understood that the various numerical numbers involved in the embodiments of the disclosure are only for convenience of description and are not used to limit the scope of the embodiments of the disclosure.

A person having ordinary skill in the art should be able to easily understand that the above description is only preferred embodiments of the disclosure and is not intended to limit the disclosure. Any modifications, equivalent replacements, and modifications made without departing from the spirit and principles of the disclosure should fall within the protection scope of the disclosure.

What is claimed is:

1. A method for mask feature optimization, comprising:
acquiring a new contour after movements of the edges of the main pattern of a mask is inward or outward by a predetermined distance;
setting a region inside the new contour as the shadow region of the main pattern when the movement is an inward movement and setting a region outside the new contour as the shadow region of the main pattern when the movement is an outward movement;
screening an acquired mask gradient field solved by inverse lithography based on the shadow region of the main pattern to keep only the mask gradient field inside the region; and
generating a sub resolution assist/inverse feature of the mask based on the screened mask gradient field.

2. The method according to claim 1, wherein if the region outside the new contour is set as the shadow region of the main pattern, the generated sub resolution assist/inverse feature is a sub resolution assist feature (SRAF), and
if the region inside the new contour is set as the shadow region of the main pattern, the generated sub resolution assist/inverse feature is a sub resolution inverse feature (SRIF).

3. The method according to claim 1, wherein the acquiring the new contour after the movement of the edges of the main pattern of the mask is inward or outward by the predetermined distance comprises:
placing a partial derivative at each point on the edges of the main pattern of the mask to acquire a vector gradient field;
integrating the vector gradient field and treating the integrated values as gray scale values to acquire a gray scale auxiliary image;
segmenting the edge of the main pattern, determining a represented position of each edge segment, modulating the gray scale value at each edge segment on the auxiliary image based on the predetermined distance and the acquired vector gradient field, and then modulating the gray scale value in its vicinity through a smoothing function, so that the gray scale value in a modulation region changes continuously to acquire an updated auxiliary image; and
intercepting the updated auxiliary image by adopting a truncation threshold, extracting a polygon contour, and treating the polygon contour as the new contour if a difference value between an edge position distance, which is calculated at each point on edges between the currently extracted polygon contour and the original main pattern, and the predetermined distance is less than a preset small value; or iteratively modulating the gray scale value of each point where the difference value is not less than the preset small value, and the ones in its vicinity on the updated auxiliary image until the difference value of each point on the finally extracted polygon contour is less than the preset small value.

4. The method according to claim 3, wherein the iteratively modulating the gray scale value of each point where the difference value is not less than the preset small value and theones in its vicinity on the updated auxiliary image specifically is:
placing a partial derivative at each point in the currently extracted polygon contour where the difference value is not less than the preset small value to acquire a new vector gradient field; and
based on the newly acquired vector gradient field, the edge position distance corresponding to each point, and the predetermined distance, modulating the gray scale value of each point on the updated auxiliary image and modulating the ones in its vicinity by adopting a smoothing function, so that the gray scale value in the modulation region changes continuously to acquire an auxiliary image that is updated again.

5. The method according to claim 4, wherein the modulating the gray scale value of each point on the updated auxiliary image specifically is: based on the current gray scale value, accumulating a product of a scalar gradient corresponding to the vector gradient field of each point of the current polygon contour and a difference value between a current edge position distance and the predetermined distance to acquire a modulated gray scale value.

6. The method according to claim 1, wherein the screening the acquired mask gradient field solved by inverse lithography based on the shadow region of the main pattern comprises:
rasterizing the shadow region of the main pattern into a gray scale pixel image, and on the gray scale pixel image, setting a pixel value deep into the shadow region of the main pattern to 1, setting a pixel value far away from the shadow region of the main pattern to 0, and setting a pixel value near the edges of the shadow region of the main pattern to smoothly transition from 1 to 0; and
performing a point-by-point operation on the pixel value of each point on the gray scale pixel image and the pixel value of each point in the mask gradient field to implement screening of the mask gradient field.

7. The method according to claim 1, wherein the screening the acquired mask gradient field solved by inverse lithography based on the shadow region of the main pattern comprises:
constructing a Boolean function whose coordinate points are located inside its contour based on the edge contour of the shadow region of the main pattern; and
screening the mask gradient field based on the Boolean function.

8. The method according to claim 1, wherein the generating the sub resolution assist/inverse feature based on the screened mask gradient field comprises:
placing a corresponding sub resolution assist or inverse feature according to a position of a ridge or a valley of the mask gradient field.

9. The method according to claim 1, wherein the generating the sub resolution assist/inverse feature based on the screened mask gradient field comprises:
setting a positive threshold and a negative threshold of the gradient field;
setting the signal value of the mask gradient field at a corresponding position to 1 and setting the signal value of the mask gradient field at the rest of positions to 0 if the region outside the new contour is set as the shadow region of the main pattern and then when the value of the mask gradient field is greater than the positive threshold; and setting the signal value of the mask gradient field at the corresponding position to 1 and setting the signal value of the mask gradient field at the rest of the positions to 0 if the region inside the new contour is set as the shadow region of the main pattern and then when the value of the mask gradient field is less than the negative threshold; and
treating a pixelated feature corresponding to the mask gradient field at the position where the setting value is 1 as the generated sub resolution assist or inverse feature.

10. The method according to claim 1, wherein the main pattern is an arbitrary curvilinear pattern or a Manhattan pattern.

11. The method according to claim 1, wherein the predetermined distance refers to MRC parameter setting.

12. A method for mask feature optimization, comprising:
acquiring two new contours acquired by moving the edges of the main pattern of a mask inward and outward by a predetermined distance;
treating a region between the two new contours as a selection region;
screening an acquired mask gradient field solved by inverse lithography based on the selection region to keep only the mask gradient field inside the region; and
treating the screened mask gradient field as an optional mask gradient field in a main pattern optimization during inverse lithography process to prevent the edges of the main pattern from moving an excessively large step during mask optimization process.

13. The method according to claim 12, wherein the predetermined distance refers to a lithography optimization parameter setting.

14. A system for mask feature optimization, comprising:
a new contour acquisition module, configured to acquire a new contour after a movement of the edges of the main pattern of a mask is inward or outward by a predetermined distance;
a shadow region acquisition module, configured to set a region inside the new contour feature as a shadow region of the main pattern when the movement is an inward movement and set a region outside the new contour as the shadow region of the main pattern when the movement is an outward movement;
a mask gradient field screening module, configured to screen an acquired mask gradient field solved by inverse lithography based on the shadow region to keep only the mask gradient field inside the region; and
an assist/inverse feature generating module, configured to generate a sub resolution assist/inverse feature of the mask based on the screened mask gradient field.

15. A system for mask feature optimization, comprising:
a new contour acquisition module, configured to acquire two new contours acquired by moving the edges of the main pattern of a mask respectively inward and outward by a predetermined distance;
a selection region determining module, configured to treat a region between the two new contours as a selection region;
a mask gradient field screening module, configured to screen an acquired mask gradient field solved by inverse lithography based on the selection region to keep only the mask gradient field inside the region; and
a mask gradient field setting module, configured to treat the screened mask gradient field as an optional mask gradient field in a main pattern optimization during inverse lithography process to prevent the edge of the main pattern from moving an excessively large step during the mask optimization process.

16. An electronic apparatus, comprising:
at least one memory, configured to store a program; and
at least one processor, configured to execute the program stored in the at least one memory, when the program stored in the at least one memory is executed, the at least one processor is configured to perform the method according to claim 1.

17. An electronic apparatus, comprising:
at least one memory, configured to store a program; and
at least one processor, configured to execute the program stored in the at least one memory, when the program stored in the at least one memory is executed, the at least one processor is configured to perform the method according to claim 12.
